(19) United States
(12) Patent Application Publication
(10) Pub. No.: US 2026/0130165 A1
(43) Pub. Date: May 7, 2026

(54) METHOD OF DETECTING ABNORMALITY IN SEMICONDUCTOR MANUFACTURING PROCESS AND PROGRAM FOR PERFORMING THE SAME

(71) Applicants: PSK INC., Hwaseong-si (KR); RTM Inc., Seoul (KR)

(72) Inventors: Tae Kyung HA, Hwaseong-si (KR); Seung Heui LEE, Hwaseong-si (KR); Yeon Mo KIM, Hwaseong-si (KR)

(21) Appl. No.: 19/377,942

(22) Filed: Nov. 3, 2025

(30) Foreign Application Priority Data
Nov. 7, 2024 (KR) 10-2024-0157150

(51) Int. Cl. H01L 21/67; G05B 19/418

(52) U.S. Cl. CPC H10P 72/0604; G05B 19/41875; G05B 2219/32368

(57) ABSTRACT

The present invention provides a method of detecting an abnormality in a semiconductor manufacturing process by analyzing light within a process chamber that processes a substrate by using plasma. The method may comprise a cluster classification operation of clustering reference light intensity data into a plurality of clusters, the reference light intensity data varying depending on a type of a removal target removed from a substrate; a reference data generation operation of generating reference data including a distribution of abnormality determination numerical values for each of the plurality of clusters; and an abnormality detection operation of determining whether the target data is abnormal by comparing target data for detecting the abnormality with the reference data.

### CROSS-REFERENCE TO RELATED APPLICATION

This application claims priority to and the benefit of Korean Patent Application No. 10-2024-0157150 filed in the Korean Intellectual Property Office on November 7, 2024, the entire contents of which are incorporated herein by reference.

### TECHNICAL FIELD

The present invention relates to a method of detecting an abnormality in a semiconductor manufacturing process and a program for performing the same.

### BACKGROUND ART

A semiconductor manufacturing process includes an etching process using plasma. In this process, a specific layer of a wafer surface is removed. An Optical Emission Spectroscopy (OES) analyzer is used to accurately detect an end point of the etching process. The OES analyzer is based on a specific OES wavelength generated from a decomposition product or a reaction product of etching gas according to a wafer process recipe. Accordingly, it is possible to determine an End Point Detection (EPD) time point of the process.

However, background knowledge of the corresponding element is required to select an appropriate OES wavelength for each element in OES analysis. The wavelength emitted is different for each element, and accurate analysis is difficult if the wavelength is not properly matched. Furthermore, since the precision of the wavelength is different for each OES measurement equipment, the wavelength may vary in decimal units. For this reason, it is very difficult to match all wavelengths one by one and check them.

In addition, even in the same process recipe, the OES reaction pattern varies depending on the layer component of the wafer. For example, the OES signal that appears when a specific layer on the wafer is etched varies depending on the material of the layer. If an abnormality is detected without classification according to the wafer layer without considering such a difference, there is a high possibility that misclassification may occur. In particular, such an error may occur when detecting an ashing rate defect.

In addition, it is common to use additional monitoring means, such as sensors, in addition to OES to detect process abnormalities more effectively. For example, environmental changes may be monitored by adding a sensor that monitors the temperature or pressure in a chamber. However, this additional equipment is expensive to install and becomes a factor that increases the complexity of the process. This degrades the efficiency of the system and there is a problem that it is unreasonable in terms of cost.

### SUMMARY OF THE INVENTION

The present invention has been made in an effort to provide a method of detecting an abnormality in a semiconductor manufacturing process that is capable of calculating end point detection time and end point detection area without knowing wavelength information of light generated when a removal target layer is removed by plasma, and a program for performing the same.

The present invention has also been made in an effort to provide a method of detecting an abnormality in a semiconductor manufacturing process that is capable of detecting an abnormality in a semiconductor manufacturing process performed in a process chamber using an optical analyzer, and a program for performing the same.

The problem to be solved by the present invention is not limited to the above-mentioned problems, and the problems not mentioned will be clearly understood by those skilled in the art from the present specification and the accompanying drawings.

An exemplary embodiment of the present invention provides a method of detecting an abnormality in a semiconductor manufacturing process by analyzing light within a process chamber that processes a substrate by using plasma, the method including: a cluster classification operation of clustering reference light intensity data into a plurality of clusters, the reference light intensity data varying depending on a type of a removal target removed from a substrate; a reference data generation operation of generating reference data including a distribution of abnormality determination numerical values for each of the plurality of clusters; and an abnormality detection operation of determining whether the target data is abnormal by comparing target data for detecting the abnormality with the reference data.

According to the exemplary embodiment, the abnormality detection operation may include: a cluster determination operation of determining a cluster to which the target data belongs among the clusters classified in the cluster classification operation; an abnormality determination numerical value calculation operation of calculating the abnormality determination numerical values of the target data; and an abnormality determination operation of determining whether the semiconductor manufacturing process is abnormal when the target data is collected by comparing the abnormality determination numerical values of the target data with the abnormality determination numerical values of the reference data.

According to the exemplary embodiment, the abnormality determination numerical values may include: end point time; and end point area.

According to the exemplary embodiment, The method may comprise: a wavelength selection operation of selecting at least one wavelength that satisfies a reference condition among collectible wavelengths that are collectible in the process chamber as a selected wavelength.

According to the exemplary embodiment, The method may comprise: a selected wavelength data collection operation of collecting the reference light intensity data collected when processing the substrate for the selected wavelength.

According to the exemplary embodiment, the reference condition may be that a Wasserstein distance between a first section and a second section different from a first section is measured in light intensity data for each of the collectable wavelengths, the collectable wavelengths are arranged in an order in which the Wasserstein distance is large, and then the collectable wavelengths up to the n^{th} are selected as the selected wavelengths by prioritizing the wavelength with the large Wasserstein distance.

According to the exemplary embodiment, a method of the clustering used in the cluster classification operation may be a K-means method or a hierarchical method.

In addition, the present invention provides a method of detecting an abnormality in a semiconductor manufacturing process. The method comprising: determining an abnormality of the process by comparing pre-stored reference data with target data for detecting an abnormality, wherein the reference data may include distribution data for end point time and end point area.

According to the exemplary embodiment, the reference data may be derived by clustering reference light intensity data that vary according to a type of a removal target to be removed from a substrate into a plurality of clusters, and calculating the end point time and the end point area of the reference light intensity data included in each cluster.

In addition, the present invention provides a program stored in a recording medium, the program detecting an abnormality in a semiconductor manufacturing process by analyzing light within a process chamber that processes a substrate by using plasma, wherein the program may perform an abnormality detection operation of determining an abnormality of the process by comparing pre-stored reference data with target data for detecting an abnormality, and the reference data may include distribution data for end point time and end point area.

According to the exemplary embodiment, the program further may perform a wavelength selection operation of selecting at least one wavelength that satisfies a reference condition among collectible wavelengths that are collectible in the process chamber as a selected wavelength.

According to the exemplary embodiment, the program further may perform: a cluster classification operation of clustering reference light intensity data for the selected wavelength into a plurality of clusters; and a reference data generation operation of generating reference data including a distribution of abnormality determination numerical values for each of the plurality of clusters.

According to the exemplary embodiment, the abnormality detection operation may include: a cluster determination operation of determining a cluster to which the target data belongs among the clusters classified in the cluster classification operation; and an abnormality determination numerical value calculation operation of calculating the end point time and the end point area of the target data.

According to the exemplary embodiment, the abnormality detection operation may include: an abnormality determination operation of determining whether the semiconductor manufacturing process is abnormal when the target data is collected by comparing the end point time and the end point area of the target data with the end point time and the end point area of the reference data.

According to the exemplary embodiment of the present invention, it is possible to calculate an end point detection time and an end point detection area without knowing wavelength information of light generated when a removal target layer is removed by plasma.

In addition, according to the exemplary embodiment of the present invention, it is possible to detect whether a semiconductor manufacturing process performed in the process chamber is abnormal by using an optical analyzer.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

FIG. 1 is a diagram for schematically describing a substrate processing apparatus according to an exemplary embodiment of the present invention.

FIG. 2 is a flowchart illustrating an abnormality detection method according to an exemplary embodiment of the present invention.

FIG. 3 is a diagram for describing wavelength candidates that may be selected as a selected wavelength in a wavelength selection operation of FIG. 2.

FIG. 4 is a diagram illustrating a method of selecting a selected wavelength from among wavelength candidates in the wavelength selection operation of FIG. 2.

FIG. 5 is a diagram illustrating an example of light intensity data of a wavelength that may be selected as a selected wavelength in the wavelength selection operation of FIG. 2.

FIG. 6 is a diagram illustrating an example of light intensity data having a wavelength that is difficult to be selected as a selected wavelength in the wavelength selection operation of FIG. 2.

FIG. 7 is a graph illustrating light intensity data that may be collected when a plurality of substrates is processed using the same process recipe.

FIG. 8 is a clustered graph of light intensity data that may be collected when a plurality of substrates is processed using the same process recipe.

FIG. 9 is a distribution diagram illustrating an end point time distribution and end point area distribution for each cluster.

FIG. 10 is a graph for describing the end point time distribution and the end point area distribution of FIG. 9.

FIG. 11 is a flowchart illustrating the abnormality detection operation of FIG. 2.

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms "a,” "an," and "the" may be intended to include the plural forms as well, unless the context clearly indicates otherwise. The terms "comprises," "comprising," “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being "on," “engaged to,” "connected to," or "coupled to" another element or layer, it may be directly on, engaged, connected or coupled to the other element or layer, or intervening elements or layers may be present. In contrast, when an element is referred to as being "directly on," “directly engaged to,” "directly connected to," or "directly coupled to" another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term "and/or" includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” "beneath," "below," "lower," "above," "upper," and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as "below" or "beneath" other elements or features would then be oriented "above" the other elements or features. Thus, the example term "below" can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms "about" or “substantially” are used in connection with a numerical value, it should be understood that the associated numerical value includes a manufacturing or operational tolerance (e.g., ±10%) around the stated numerical value. Moreover, when the words "generally" and "substantially" are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

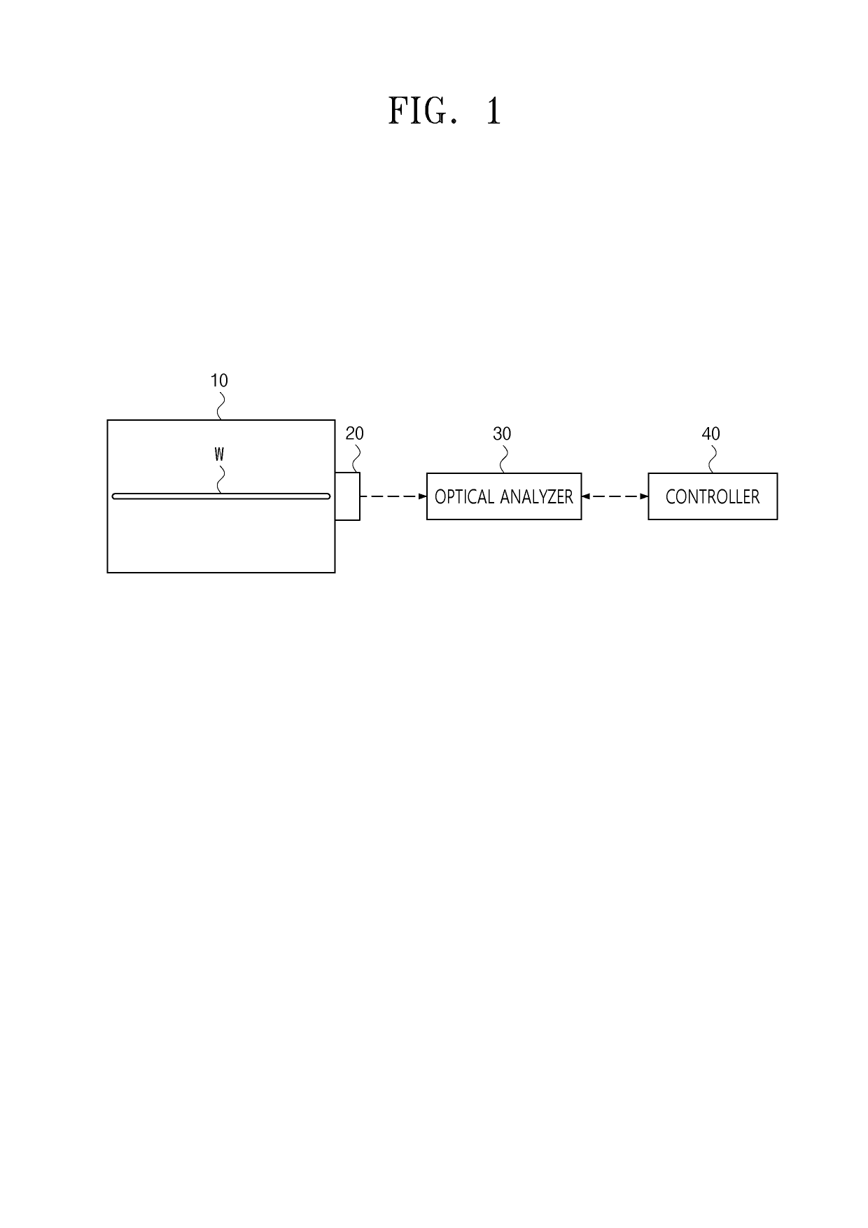

FIG. 1 is a diagram for schematically describing a substrate processing apparatus according to an exemplary embodiment of the present invention.

The substrate processing apparatus 1 according to the present invention includes a process chamber 10, an optical sensor 20, an optical analyzer 30, and a controller 40. Through these components, a substrate W is processed using plasma, and an abnormality in the process may be detected based on data generated during the process.

The process chamber 10 is a chamber capable of processing a substrate, such as a wafer W, using plasma. Plasma is ionized gas in a high energy state and may be used for operations, such as etching, deposition, and cleaning, in semiconductor manufacturing processes.

The plasma process may be performed by ionizing the gas by applying electrical energy to the gas. When the gas is ionized, electrons and ions are generated, and these high-energy particles collide with the surface of the substrate, so that specific materials on the substrate may be removed or new materials may be deposited. Unnecessary layers may be removed in the etching process, and a new layer may be formed on the surface of the substrate in the deposition process. Also, residue or impurities remaining on the surface of the substrate may be effectively removed in the cleaning process.

The process chamber 10 may have a power supply device that generates plasma by supplying power. The power supply device may transfer energy to gas and ionize the gas using high-frequency (RF) power or microwave power. The density and stability of plasma may be controlled through the power supply device. RF power generated by the power supply device may be applied into the process chamber 10 through components, such as an antenna or a counter electrode, through which gas may be effectively ionized to form plasma. The power supply device, the antenna or the power supply device, and the counter electrode may be defined as a plasma source.

In addition, the process chamber 10 may include a gas supply system that supplies process gas required to form plasma. Gas used in the etching process includes CF₄, SF, and O₂, and gas, such as SiH₄ or NH₃, may be used in the deposition process.

The process chamber 10 may also include a pressure control system for controlling the pressure inside the chamber. Since plasma may be stably maintained under specific pressure conditions, plasma may be appropriately formed during the process through a pressure control system including a pump and the like, and a desired process may be consistently performed.

In addition, the process chamber 10 may include a substrate holder that accurately controls the position of the substrate. The substrate holder fixes the substrate during the process, and may ensure uniform plasma treatment and stable process results.

In addition, the process chamber 10 may include various components required to perform a process of processing a substrate using plasma. For example, a magnetic field generating device for ensuring uniformity of plasma generation may be added.

The optical sensor 20 may detect light generated inside the process chamber through a view port provided on a sidewall of the process chamber 10. The light emitted during the plasma process is important information indicating a process state, and the optical sensor may detect the light in real time to collect data necessary for process monitoring.

The detected light may be transmitted to the optical analyzer 30 through an optical cable. The optical sensor 20 may convert the detected optical signal into an analog or digital signal and transmit the converted analog or digital signal to the optical analyzer 30. These signals may be processed by the optical analyzer 30 to provide important data for analyzing a process state or determining whether there is an abnormality.

Various technologies may be used as the optical sensor 20. The photodiode sensor may convert light into an electrical signal based on a semiconductor material, and is characterized by high-speed responsiveness. A Charge-Coupled Device (CCD) sensor may capture a high-resolution optical image to enable precise optical analysis. A Component Metal-Oxide-Semiconductor (CMOS) sensor may provide low power consumption and high degree of integration. The optical fiber sensor may perform stable optical signal transmission even in high temperature and harsh environments.

The optical analyzer 30 is a device that analyzes an optical emission spectrum emitted during a plasma process in the process chamber 10 and is based on Optical Emission Spectroscopy (OES) technology. Plasma emits light of various wavelengths in a high energy state, and the light may provide important information about the state of the process and the chemical reaction. The optical analyzer 30 may analyze the optical signal to monitor the state of the process in real time or detect an abnormality.

The optical analyzer 30 may receive light emitted from the plasma collected through the optical sensor 20 and analyze the wavelength, intensity, distribution, and the like of the corresponding light. Each wavelength corresponds to a specific element or molecule, and through this, it is possible to determine what reaction is taking place in the current process and what chemical components are being generated or removed. For example, when light of a specific wavelength is detected in the plasma, this may be a signal that specific gas or material is reacting during the process.

OES plays an important role in End Point Detection (EPD) in a semiconductor manufacturing process. The optical analyzer 30 may determine whether the process reaches a desired level by monitoring the light emitted while a specific layer of the substrate W is removed. The spectrum of light is changed while the layer is removed in the etching process, and an accurate end point may be detected by analyzing the change.

The optical analyzer 30 provides various spectral resolutions and analysis ranges, so that a wide range of wavelengths may be detected and analyzed. Through this, even minute changes occurring in the plasma may be detected, and small fluctuations or abnormalities in the process may be detected in real time. This analysis result is transmitted to the controller 40 to automatically adjust the process state, or to enable an immediate response when an abnormality occurs during the process.

The optical analyzer 30 may also be set according to various substrates and process conditions. For example, since the reaction of each wavelength may be different according to the layer characteristics of a specific substrate, reference data for each wavelength used during the process may be set in advance, and based on the preset reference data, it is possible to evaluate whether the process is proceeding normally. Through this setting, customized analysis according to the material of the substrate or the process gas is possible.

In addition, since the optical analyzer 30 has a high-speed analysis function, the optical analyzer 30 may respond immediately to rapid changes in the plasma process. In particular, the optical analyzer 30 may contribute to increasing the accuracy of the process by performing precise wavelength analysis even in a complex process environment.

The controller 40 may include a memory, a processor, a display, an interface unit, and a bus.

Various components, such as a memory, a processor, a display, and an interface unit, may be connected to and communicate with each other (i.e., transmitting a control message and transmitting data) by a bus.

The memory may include volatile memory (e.g., DRAM, SRAM, or SDRAM) and/or nonvolatile memory (e.g., One Time Programmable ROM (OTPROM), PROM, EPROM, EEPROM, mask ROM, flash ROM, flash memory, PRAM, RRAM, MRAM, hard drive, or Solid State Drive (SSD)). The memory may include an internal memory and/or an external memory. The memory may store, for example, commands or data related to at least one other component of the electronic device. Also, the memory may store software and/or programs. The program may include, for example, a kernel, middleware, an Application Programming Interface (API), and/or an application program (or "application"). At least some of the kernel, middleware, or API may be referred to as an operating system.

In addition, a non-transitory computer readable medium may be provided to the controller 40. The non-transitory computer-readable medium refers to a medium that stores data semi-permanently and is readable by a computer, rather than a medium that stores data for a short moment, such as a register, cache, and memory. Specifically, the above-described various applications or programs may be stored and provided on a non-transitory readable medium, such as a CD, DVD, hard disk, Blu-ray disk, USB, memory card, or ROM. Examples of program instructions include not only a mechanical code, such as that is made by a compiler, but also an advanced language code that may be executed by a computer using an interpreter or the like. The above-described hardware device may be configured to operate as one or more software modules to perform the operations of the present invention, and vice versa.

The processor may include one or more of a central processing unit, an application processor, or a Communication Processor (CP). The processor may perform, for example, operations or data processing related to control and/or communication of at least one other component of a computing device or non-transitory computer-readable medium.

The display may include, for example, a Liquid Crystal Display (LCD), a Light Emitting Diode (LED) display, an Organic Light Emitting Diode (OLED) display, a Micro Electromagnetic System (MEMS) display, or an electronic paper display. The display may display, for example, various contents (e.g., text, images, videos, icons, and/or symbols) to the user. The display may include a touch screen, and may receive, for example, a touch, gesture, proximity, or hovering input using an electronic pen or a part of the user's body.

The interface unit allows the computing device to communicate with the outside over a network. Here, the network includes both wired and wireless methods. In particular, wireless communication may include, for example, cellular communication using at least one of LTE, LTE-Advance (LTE-A), Code Division Multiple Access (CDMA), Wideband CDMA (WCDMA), Universal Mobile Telecommunications System (UMTS), Wireless Broadband (WiBro), or GSM (Global System for Mobile Communications). Alternatively, wireless communication may include at least one of Wireless Fidelity (WiFi), Light Fidelity (LiFi), Bluetooth, Bluetooth low power (BLE), Zigbee, Near Field Communication (NFC), magnetic secure transmission, Radio Frequency (RF), or Body Area Network (BAN). Alternatively, wireless communication may include GNSS. For example, GNSS may include at least one of Global Positioning System (GPS), Global navigation satellite system (Glonass), Beidou navigation satellite system (hereinafter referred to as "Beidou"), or Galileo, the European global satellite-based navigation system. Wired communication may include, for example, Universal Serial Bus (USB), High Definition Multimedia Interface (HDMI), Recommended Standard 232 (RS-232), power line communication, or computer network (e.g., LAN or WAN).

Hereinafter, an abnormality detection method according to an exemplary embodiment of the present invention will be described in detail. In addition, the abnormality detection method described below may be implemented by executing a program stored in a recording medium included in the above-described controller 40 by a processor.

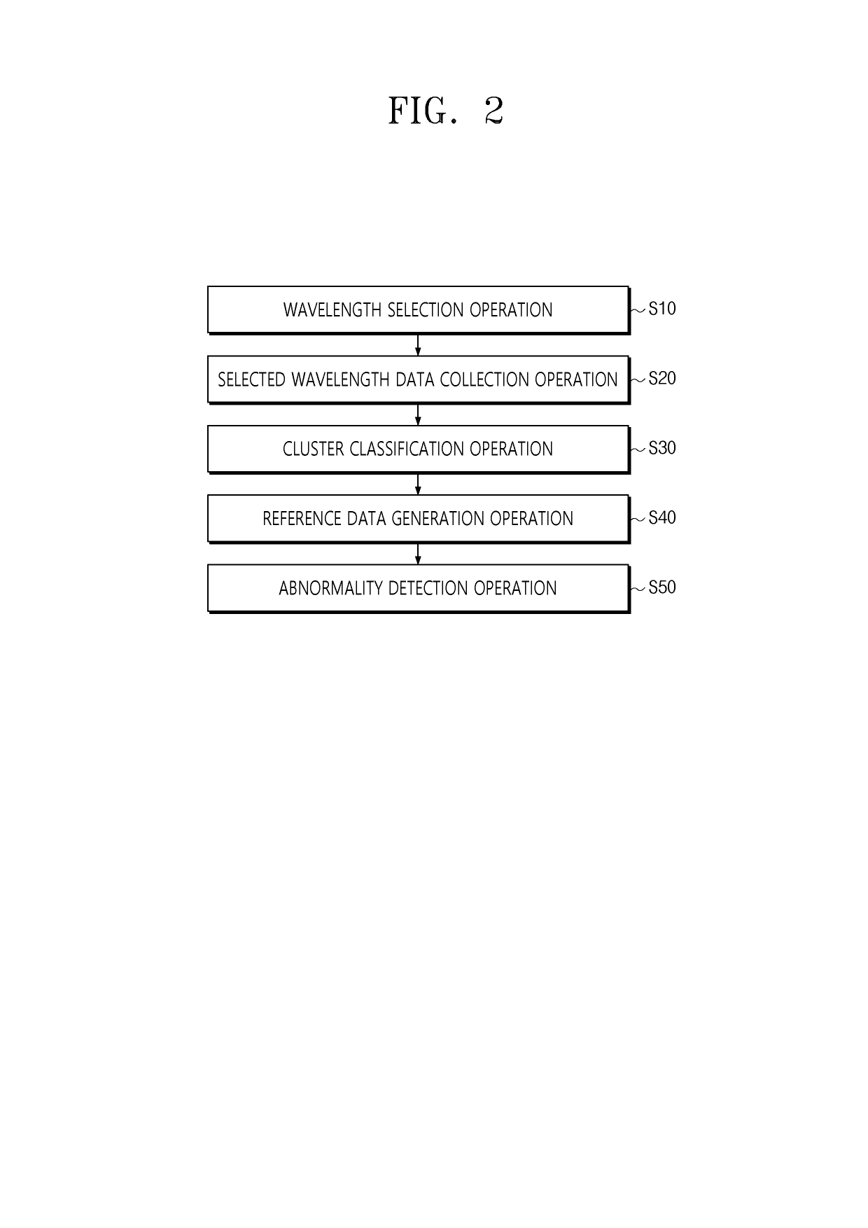

FIG. 2 is a flowchart illustrating an abnormality detection method according to an exemplary embodiment of the present invention.

Referring to FIG. 2, an abnormality detection method according to an exemplary embodiment of the present invention may include a wavelength selection operation S10, a selected wavelength data collection operation S20, a cluster classification operation S30, a reference data generation operation S40, and an abnormality detection operation S50.

In the wavelength selection operation S10, the optical analyzer 30 may select at least one wavelength satisfying a reference condition among the collectible wavelengths that may be collected by the optical analyzer 30 in the process chamber 10 as a selected wavelength.

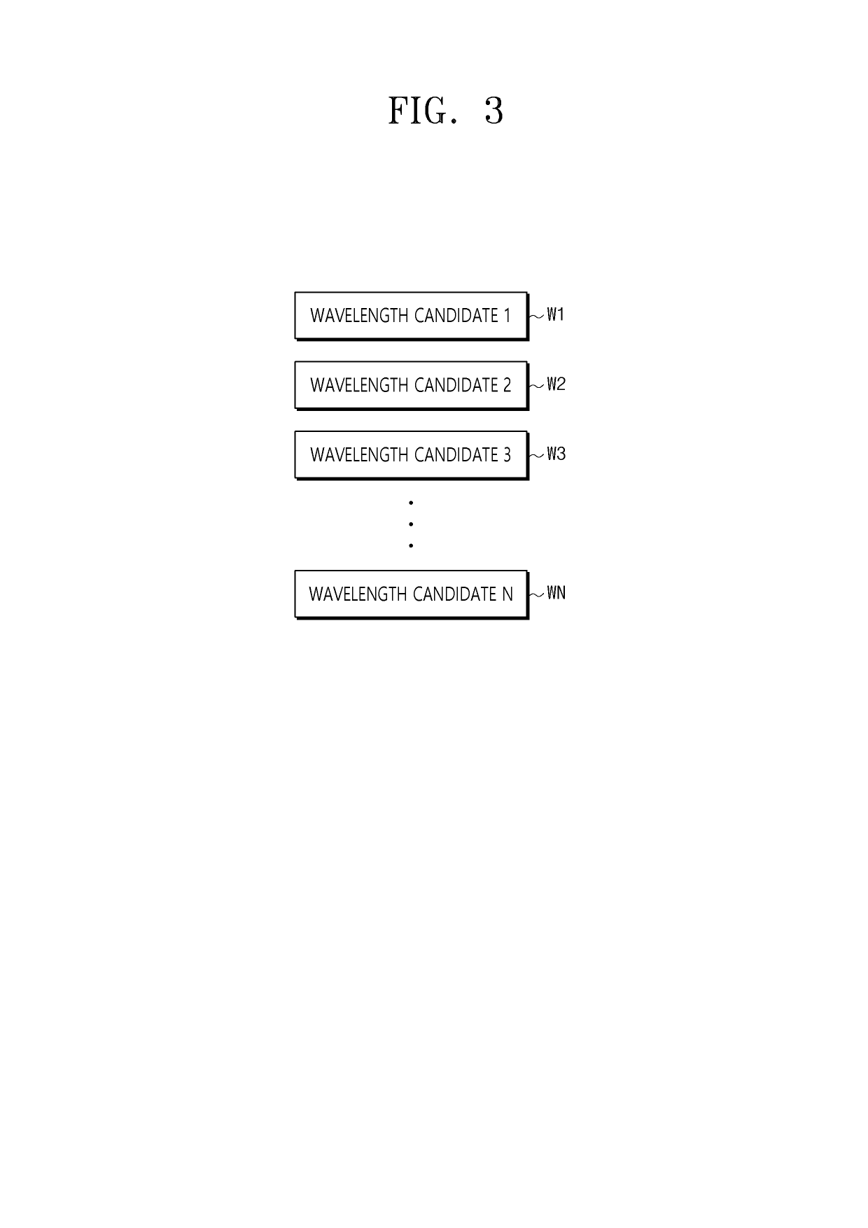

FIG. 3 is a diagram for describing wavelength candidates that may be selected as a selected wavelength in the wavelength selection operation of FIG. 2. In detail, as illustrated in FIG. 3, light having various wavelengths may be generated in the process chamber 10 while performing a plasma treatment process on the substrate W. The range of wavelengths that the optical analyzer 30 may collect in the process chamber 10 may be 200 nm to 1000 nm, and the number of variables (i.e., the number of wavelength candidates) may be 1500 or more. That is, wavelength candidates W1, W2, W3, … WN, which are wavelengths that the optical analyzer 30 may collect in the process chamber 10 (N is a natural number) may be plural.

Among the wavelength candidates WN, a wavelength to be used for determining a process abnormality may be selected. Hereinafter, a wavelength selected as a wavelength to be used in determining a process abnormality may be defined as a selected wavelength.

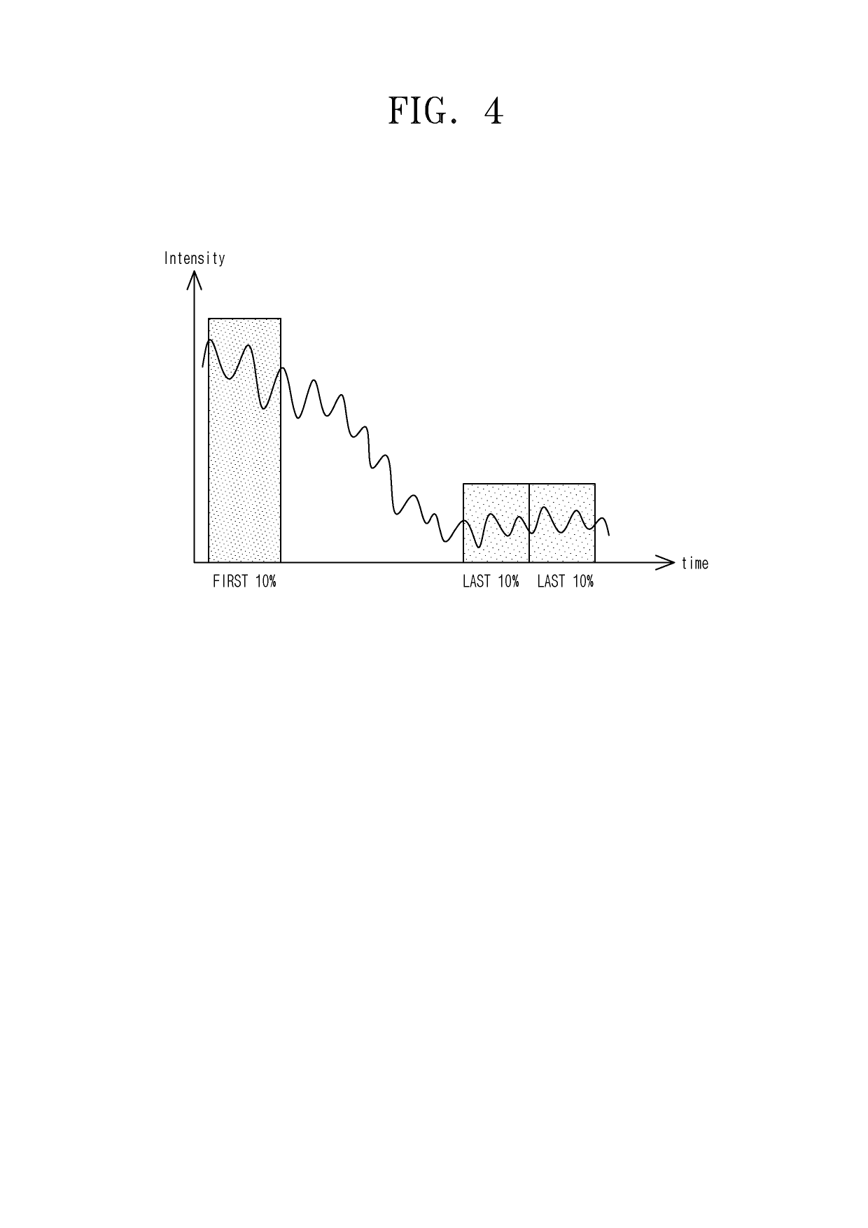

FIG. 4 is a diagram illustrating a method of selecting a selected wavelength from among wavelength candidates in the wavelength selection operation of FIG. 2.

Referring to FIG. 4, the selected wavelength, which is the wavelength to be used for determining a process abnormality among the wavelength candidates WN, may be a wavelength that satisfies a preset reference. A reference condition, which is a preset reference, may be defined as a case in which a difference between the light intensity at the early stage of the process and the light intensity at the late stage of the process is relatively large. In order to select a wavelength satisfying the reference condition among the wavelength candidates WN, a plurality of substrates W may be processed, and light intensity data for the light generated at this time may be collected as a normal process sample through the optical analyzer 30. In addition, the normal process sample may be stored in the controller 40.

The graph illustrated in FIG. 4 is a graph illustrating a change in light intensity of a specific wavelength in the light intensity data collected when the substrate W is normally processed. When a process is performed, a process may be divided into a plurality of sections. The user may set the size of each section. For example, when 10% of the total time of the process is set to the size of each section, when one process is performed, the process may be divided into 10 sections. In this case, the controller 40 may measure the Wasserstein distance between a start section (an example of a first section, the first 10%) and a representative section (an example of a second section, the last 10% of the last process), which is the last section, using a pre-stored algorithm. The Wassstein distance may be a measure used to measure the distance between two probability distributions.

As the Wassstein distance is larger, the wavelength may be the wavelength having the greater change in light intensity between the start section and the last section of the process. The controller 40 measures the Wassstein distance from the normal process light intensity data for each of the wavelength candidates WN, and lists the candidate wavelengths W in order from the large Wassstein distance measured. In addition, it is possible to select the wavelength candidates WN up to the n^{th} preset by the user as the selected wavelengths. The larger the Wassstein distance, the greater the difference in light intensity between the early stage of the process and the late stage of the process. The large difference in intensity between the early stage of the process and the late stage of the process of light in a specific wavelength band makes it possible to estimate that the light of the corresponding wavelength is generated when a removal target to be removed from the substrate W reacts with the plasma.

In addition, the user may measure not only the Wassstein distance between the start section and the representative section, but also the distance between the start section and an immediately preceding section (an example of a third section, the last 10% immediately before the last process) of the representative section, as necessary. Depending on the process, since some process noise may occur in the representative section where the process is terminated, the above problem may be solved by measuring the Wassstein distance between the immediately preceding section of the representative section and the start section.

In some cases, the sum of the Wassstein distances between the start section - the representative section, and the start section - the immediately preceding section of the representative section may be derived, and the selected wavelength may be selected based on the derived sum. For example, a wavelength candidate having a large sum may be selected as a selected wavelength. This is to enable the other of the representative section and the immediately preceding section of the representative section to supplement the noise when noise is generated in the light intensity data in any one of the representative section and the immediately preceding section of the representative section.

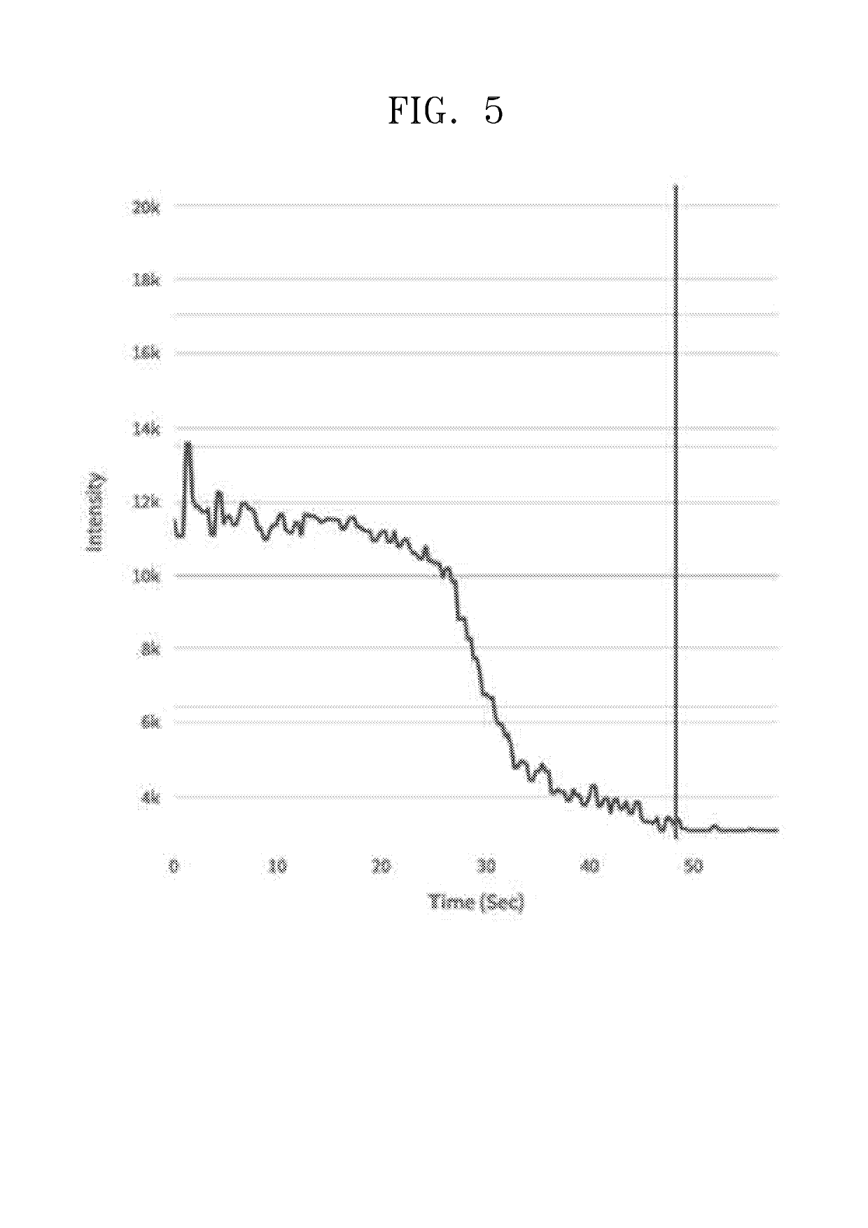

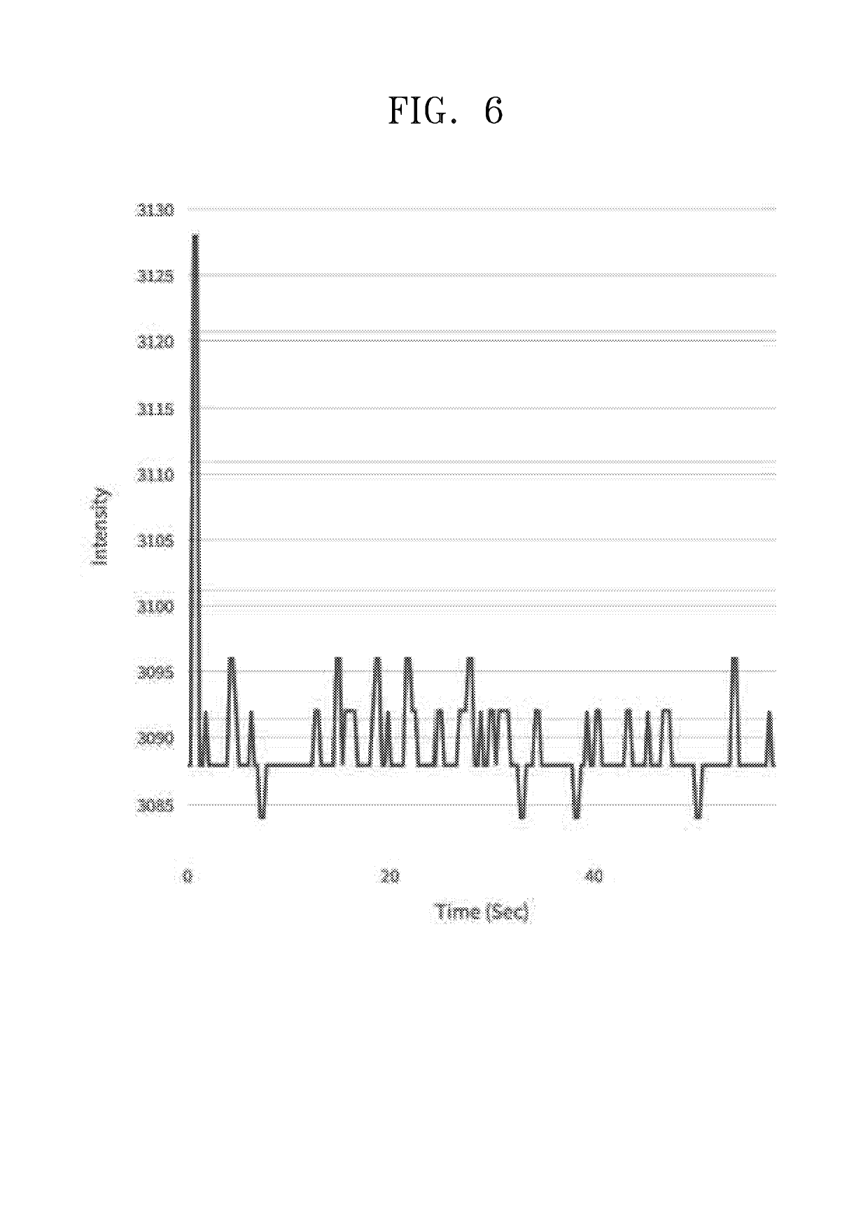

In the above method, the wavelength candidate WN satisfying the reference condition is selected as the selected wavelength. For example, as illustrated in FIG. 5, a wavelength having a large difference in light intensity between the early stage of the process and the late stage of the process is selected as a selected wavelength, and as illustrated in FIG. 6, a wavelength having a small difference in light intensity between the early stage of the process and the late stage of the process may be difficult to be selected as a selected wavelength.

Referring back to FIG. 2, in the selected wavelength data collection operation S20, light intensity data for the selected wavelength selected in the wavelength selection operation S10 may be collected. For example, when the selected wavelengths are 200 nm and 300 nm, light intensity data for 200 nm and light intensity data for 300 nm, which are collected while the substrate W is processed in the process chamber 10, may be collected for each selected wavelength.

The above light intensity data may be defined as reference light intensity data. The reference light intensity data may be collected by performing a process on an additional substrate W after the wavelength selection operation S10 is completed, or alternatively, by collecting light intensity data for the selected wavelength in the above-described normal process sample.

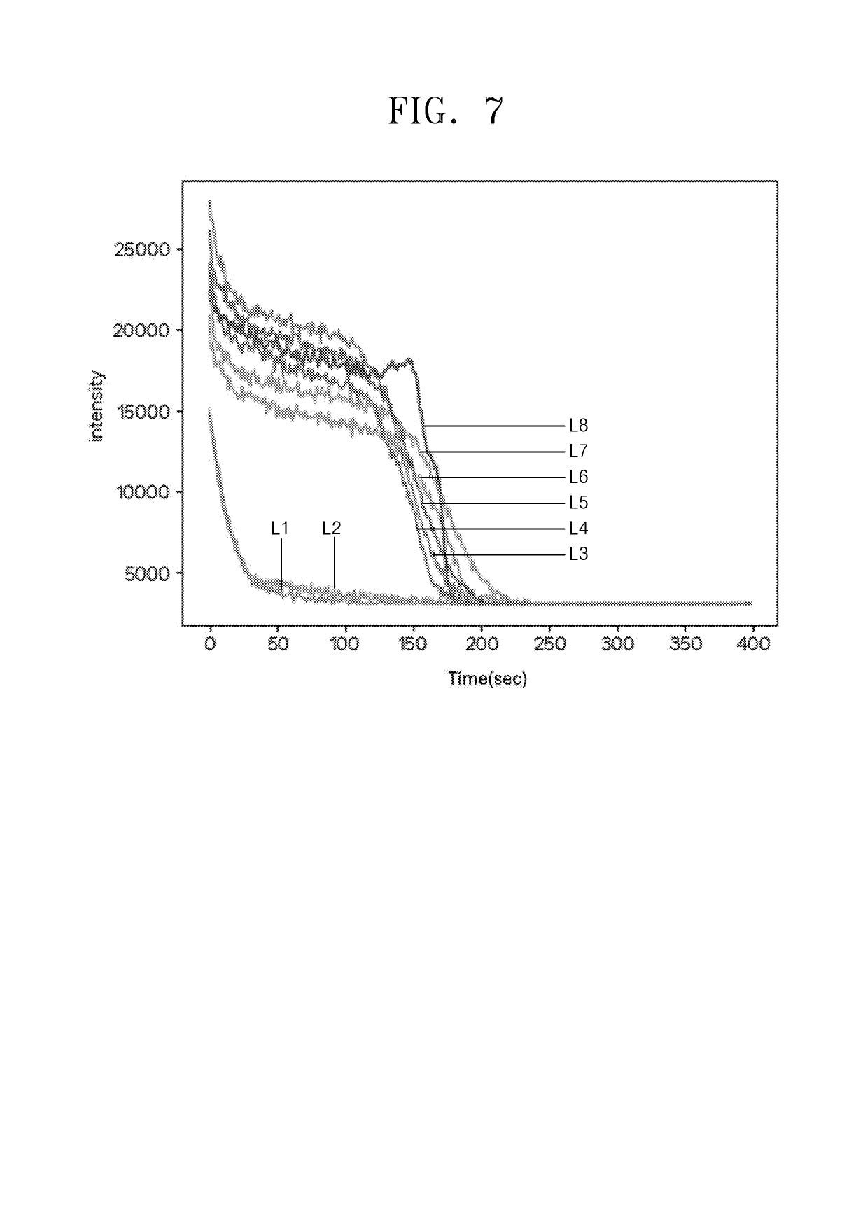

As illustrated in FIG. 7, the reference light intensity data may exhibit slightly different aspects. FIG. 7 represents the change in light intensity over time at a specific wavelength (e.g., 200 nm wavelength) when the process chamber is operated with the same process recipe (for example, when the process is performed by equally controlling the intensity of power, the pressure in the chamber, the flow rate of the supplied process gas, and the like. As illustrated in FIG. 7, L1 and L2 show similar aspects, and L3 to L8 show similar aspects. L1 to L8 may be light intensity collected when different substrates W are respectively processed with the same process recipe, and may be reference light intensity data defined above.

In this way, when the process chamber 10 is operated using the same process recipe and a change in light intensity of the same wavelength is observed, reference light intensity data exhibiting different aspects may be collected, which may vary depending on the type of material of the removal target to be removed from the substrate W. For example, when the removal target to be removed from the substrate W is a first layer provided with material A, and the removal target to be removed is a second layer provided with material B, the observed light intensity change data may be different.

Referring back to FIG. 2, in the cluster classification operation S30, reference light intensity data that vary according to the type of removal target removed from the substrate W may be clustered into a plurality of clusters.

Specifically, the controller 40 may cluster the reference light intensity data through a pre-stored cluster algorithm. The cluster algorithm is a technique for defining clusters among similar data, and the K-means methodology, which is a supervised learning methodology, may be used as a clustering technique if a user wants to define the number of clusters, and the hierarchical methodology may be used as a clustering technique if the user does not know the number of clusters. Through the cluster algorithm as described above, the reference light intensity data may be divided into a plurality of clusters.

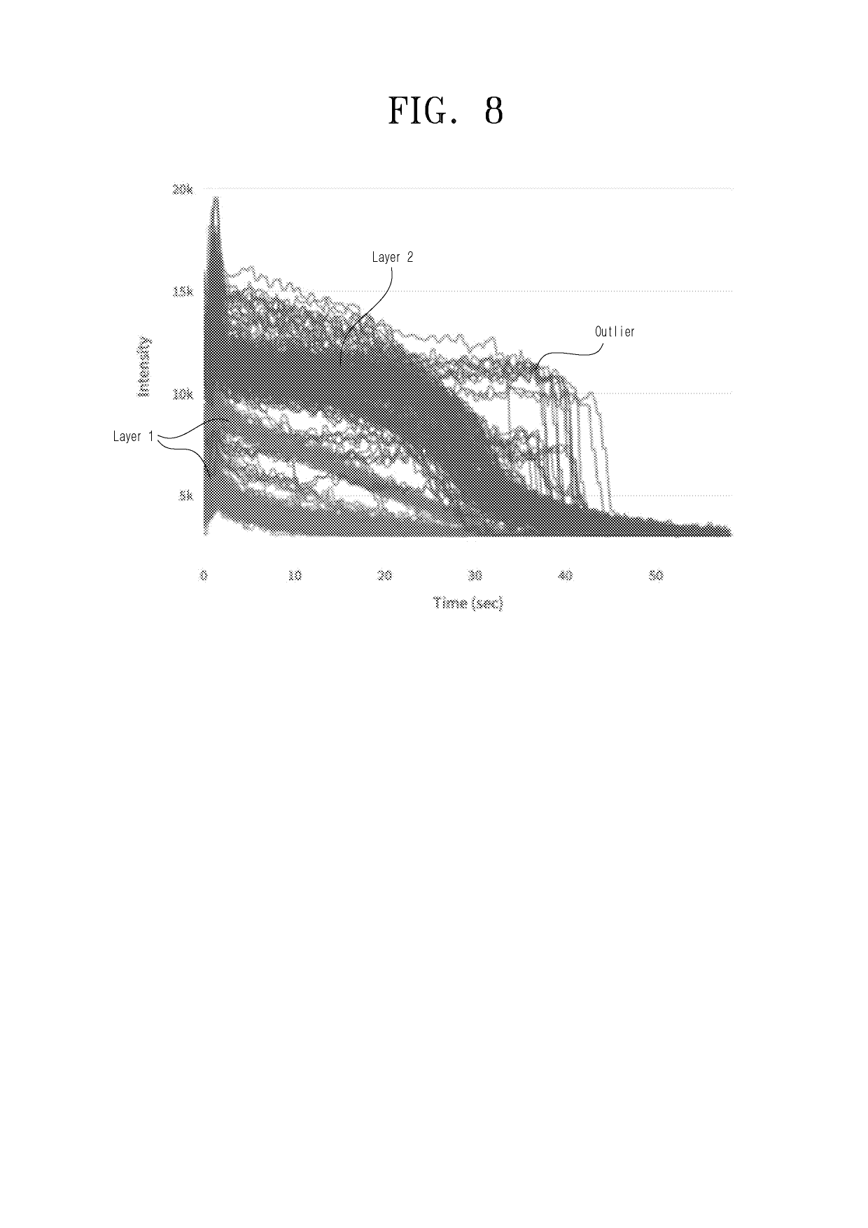

In the exemplary embodiment of the present invention, as illustrated in FIG. 8, when the removal target is the first layer provided with the material A, the removal target is classified as a first group, when the removal target is the second layer provided with the material B, the removal target is classified as a second group, and otherwise, it is determined as an outlier. And, when clusters are formed, a representative waveform for each cluster to be used in a cluster determination operation S51 described below may be separately stored in the controller 40. For example, the representative waveform for each cluster may be an average of reference data belonging to each cluster.

Referring back to FIG. 2, in the reference data generation operation S40, reference data to be used when determining whether the target data is abnormal in the abnormality detection operation S50 to be described later may be generated. The reference data may be derived by clustering reference light intensity data that vary according to the type of removal target to be removed from the substrate W into a plurality of clusters, and calculating end point time and end point area of the reference light intensity data included in each cluster.

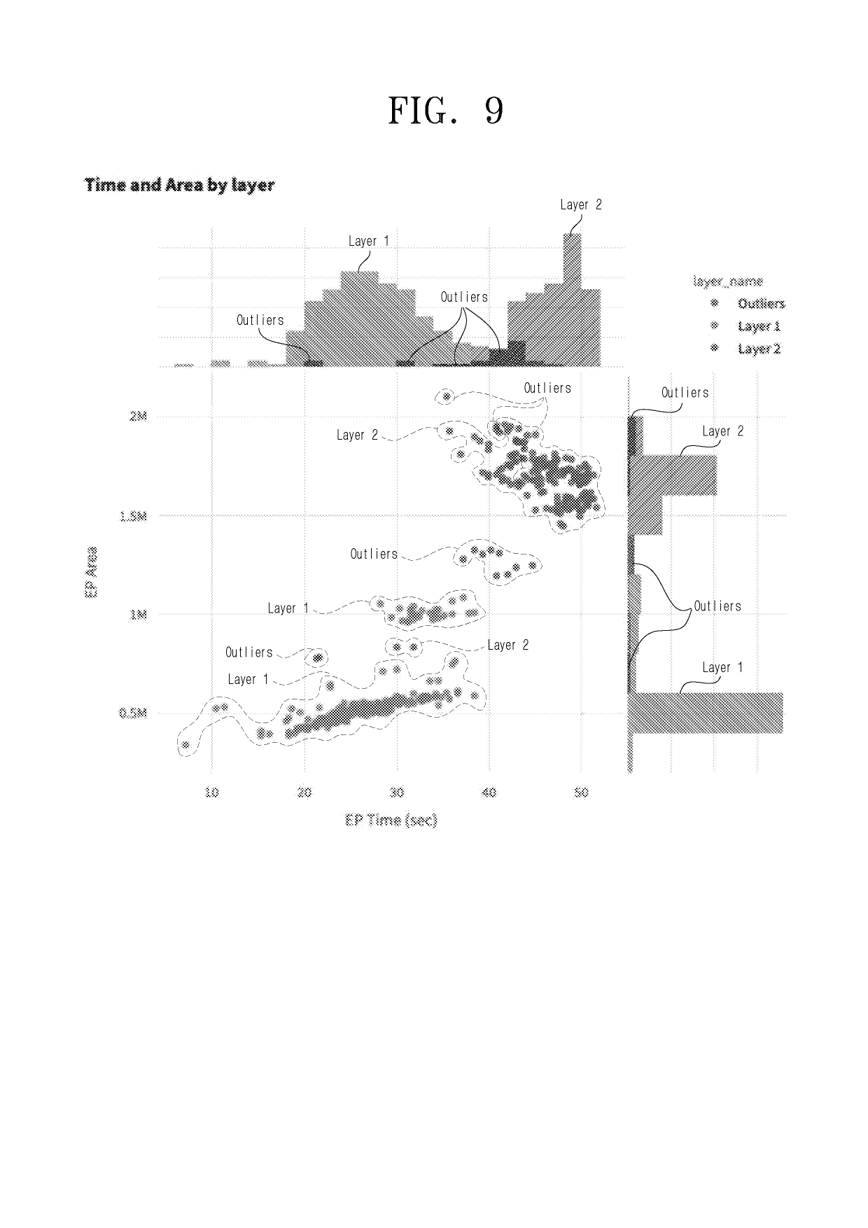

FIG. 9 is a distribution diagram illustrating an end point time distribution and end point area distribution for each cluster.

FIG. 9 illustrates distributions of abnormality determination values of the reference light intensity data belonging to the first group and abnormality determination values of the reference light intensity data belonging to the second group, and the distribution diagram illustrated in FIG. 9 may be an example of reference data defined in the present invention. The abnormality determination values may include the end point time and end point area. It is possible to determine whether there is an abnormality in a process when collecting target data based on the abnormality determination values obtained from the reference data as illustrated in FIG. 9 and target data to be described below.

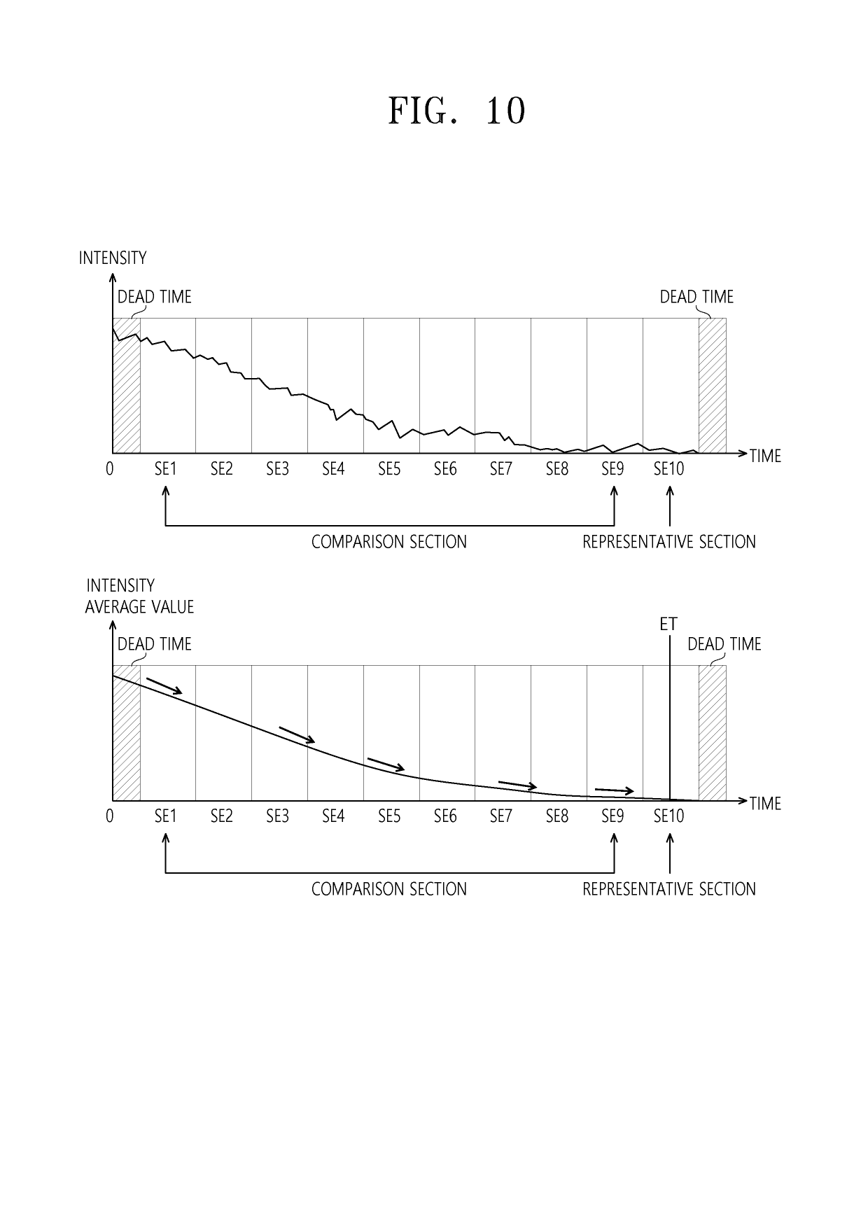

FIG. 10 is a graph for describing the end point time distribution and the end point area distribution of FIG. 9.

Referring to FIG. 10, first, in the entire process time, the set time after the process recipe is started and the set time before the process recipe is finished are dead time, and data collected at the corresponding time is excluded when calculating the end point time and the end point area. The dead time may be designated with the set time after the plasma is on (i.e., the power supply of the power supply is on), and the set time before the plasma is off (i.e., the power supply of the power supply is off).

In addition, the remaining time zone is divided into a plurality of sections while excluding the dead time. For example, a section SE10 belonging to the last 10% of the plurality of sections SE1 to SE10 may be set as a representative section (an example of the first section), and the remaining sections SE1 to SE9 may be set as comparison sections (an example of the second section). In the case of the etching (or ashing) process, in order to completely etch (or ash) the removal target on the substrate W, an over-etching (ashing) is performed longer than the existing process time, which corresponds to the last 10% section of the normal process. Accordingly, the section SE10 belonging to the last 10% section is set as the representative section.

In addition, an average value of light intensity of the reference optical data belonging to each cluster is calculated. In addition, a reference time point ET for detecting the end point, which is an end point of the etching process, is selected. In the representative section SE10, a time point at which the slope with respect to the intensity of light of the wavelength enters within a set slope may be selected as the reference time point ET.

When the user derives the above-described set slope from the light intensity average value, the reference time ET of each reference optical data is derived based on the corresponding setting slope.

In addition, the time taken from the start of the process recipe excluding the dead time to the reference time point ET is defined as the end point time, and the area of the lower part of the graph is defined as the end point area.

The distribution diagram of FIG. 9 described above displays the end point time and the end point area as defined above of each reference optical data belonging to each cluster.

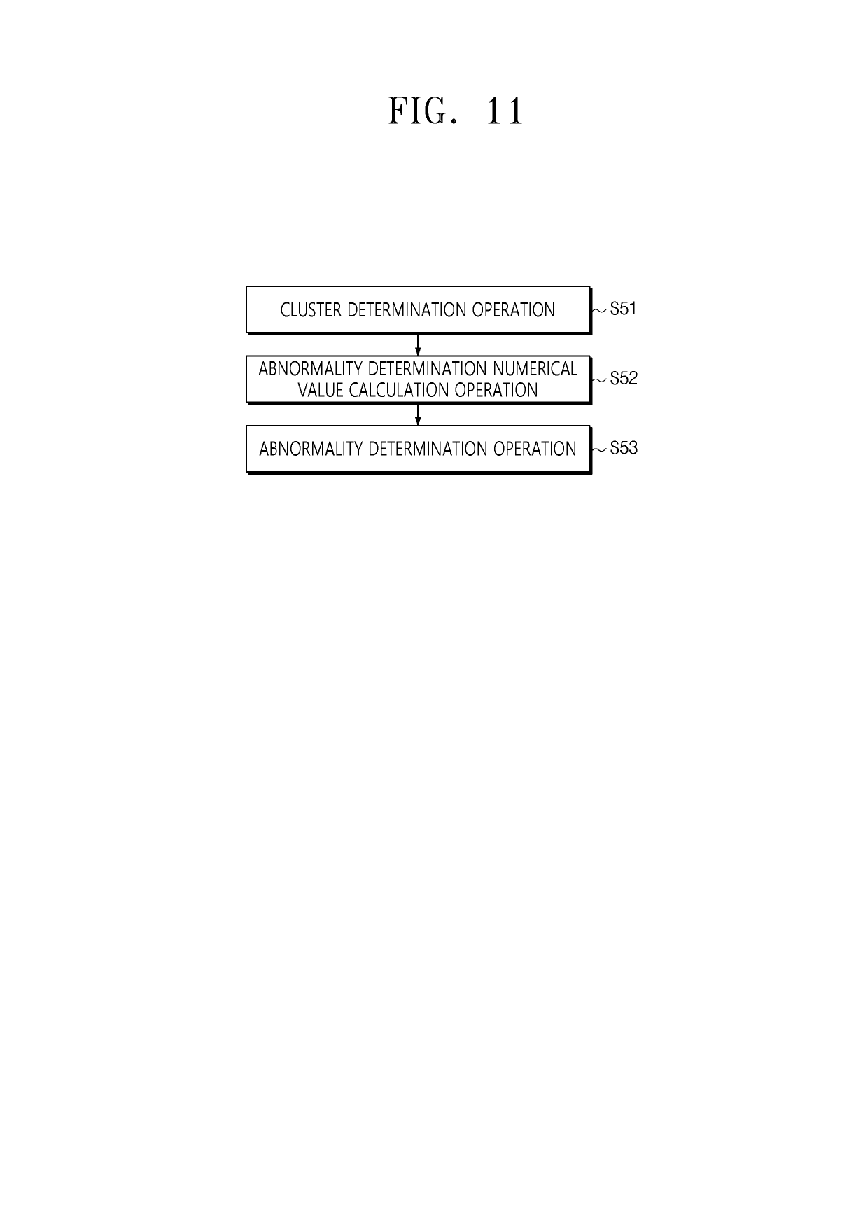

FIG. 11 is a flowchart illustrating the abnormality detection operation of FIG. 2.

Referring to FIGS. 2 and 11, in the abnormality detection operation S50, target data to be determined is compared with reference data to determine whether the target data is abnormal. When an abnormality occurs in the target data, it may be estimated that an abnormality has occurred in the semiconductor manufacturing process when the target data is collected.

When the abnormality detection operation S50 is performed, the previously performed wavelength selection operation S10, selected wavelength data collection operation S20, cluster classification operation S30, and reference data generation operation S40 may be performed in advance, and through this, the reference data may be generated in advance.

In order to perform the abnormality detection operation S50, the process chamber 10 performs a processing process on the substrate W, and through this, target data, which is light intensity data for the selected wavelength, may be collected. When the target data is collected through the optical analyzer 30, the controller 40 may extract light intensity data for a previously selected selected wavelength from the target data. And, by performing a cluster determination operation S51 on the extracted light intensity data, it is determined whether the extracted light intensity data belongs to the first group and the second group. In the cluster determination operation S51, the cluster algorithm used in the cluster classification operation S30 described above may be equally applied. Accordingly, when the target data is collected, the material of the removal target to be removed from the substrate W may be estimated.

Thereafter, the controller 40 may perform an abnormality determination numerical value calculation operation S52 of calculating an abnormality determination numerical value from the target data. The abnormality determination numerical value may be the end point time and end point area described above.

Thereafter, the controller 40 may perform an abnormality determination operation S53 of detecting whether the process is abnormal when collecting the target data by comparing the abnormality determination numerical values of the target data with the abnormality determination numerical values of the reference data. For example, in the abnormality determination numerical value distribution illustrated in FIG. 9, the controller 40 connects numerical value distributions located at the outermost side of each cluster in a closed loop, and may determine whether the process is abnormal depending on whether the abnormality determination numerical value of the target data is located inside the region defined by the closed loop. When the abnormality determination numerical value of the target data is located inside the region, the controller may determine that the process is normal, and when the abnormality determination numerical value of the target data is located outside the region, the controller may determine that the process is abnormal.

Alternatively, the average value of each cluster is calculated from the reference data, and when the distance between the calculated average value and the abnormality determination numerical value distribution of the target data is equal to or greater than a set distance, it may be determined that the process is abnormal, and when the distance is less than the set distance, it may be determined that the process is normal. In particular, the present invention determines a process abnormality by considering not only end point time but also end point time. This is because when a process abnormality is determined only by end point time, a process abnormality occurring in the middle of the process cannot be properly identified, and when a process abnormality is determined only by end point area, an excessively long process time cannot be properly detected.

In addition, the present invention divides each data into a plurality of clusters through normal process sample data collected in advance, and first determines a cluster to which the target data belongs among the plurality of clusters. Through this, it is possible to accurately determine whether the process is abnormal even when the type of removal target is different.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A method of detecting an abnormality in a semiconductor manufacturing process by analyzing light within a process chamber that processes a substrate by using plasma, the method comprising:
a cluster classification operation of clustering reference light intensity data into a plurality of clusters, the reference light intensity data varying depending on a type of a removal target removed from a substrate;
a reference data generation operation of generating reference data including a distribution of abnormality determination numerical values for each of the plurality of clusters; and
an abnormality detection operation of determining whether the target data is abnormal by comparing target data for detecting the abnormality with the reference data.

2. The method of claim 1, wherein the abnormality detection operation includes:
a cluster determination operation of determining a cluster to which the target data belongs among the clusters classified in the cluster classification operation;
an abnormality determination numerical value calculation operation of calculating the abnormality determination numerical values of the target data; and
an abnormality determination operation of determining whether the semiconductor manufacturing process is abnormal when the target data is collected by comparing the abnormality determination numerical values of the target data with the abnormality determination numerical values of the reference data.

3. The method of claim 2, wherein the abnormality determination numerical values include:
end point time; and
end point area.

4. The method of claim 1, further comprising:
a wavelength selection operation of selecting at least one wavelength that satisfies a reference condition among collectible wavelengths that are collectible in the process chamber as a selected wavelength.

5. The method of claim 4, further comprising:
a selected wavelength data collection operation of collecting the reference light intensity data collected when processing the substrate for the selected wavelength.

6. The method of claim 5, wherein the reference condition is that a Wasserstein distance between a first section and a second section different from a first section is measured in light intensity data for each of the collectable wavelengths, the collectable wavelengths are arranged in an order in which the Wasserstein distance is large, and then the collectable wavelengths up to the n^{th} are selected as the selected wavelengths by prioritizing the wavelength with the large Wasserstein distance.

7. The method of claim 1, wherein a method of the clustering used in the cluster classification operation is a K-means method or a hierarchical method.

8. A method of detecting an abnormality in a semiconductor manufacturing process, the method comprising:
determining an abnormality of the process by comparing pre-stored reference data with target data for detecting an abnormality,
wherein the reference data includes distribution data for end point time and end point area.

9. The method of claim 8, wherein the reference data may be derived by clustering reference light intensity data that vary according to a type of a removal target to be removed from a substrate into a plurality of clusters, and calculating the end point time and the end point area of the reference light intensity data included in each cluster.

10. A program stored in a recording medium, the program detecting an abnormality in a semiconductor manufacturing process by analyzing light within a process chamber that processes a substrate by using plasma,
wherein the program performs an abnormality detection operation of determining an abnormality of the process by comparing pre-stored reference data with target data for detecting an abnormality, and
the reference data includes distribution data for end point time and end point area.

11. The program of claim 10, wherein the program further performs a wavelength selection operation of selecting at least one wavelength that satisfies a reference condition among collectible wavelengths that are collectible in the process chamber as a selected wavelength.

12. The program of claim 11, wherein the program further performs:
a cluster classification operation of clustering reference light intensity data for the selected wavelength into a plurality of clusters; and
a reference data generation operation of generating reference data including a distribution of abnormality determination numerical values for each of the plurality of clusters.

13. The program of claim 12, wherein the abnormality detection operation includes:
a cluster determination operation of determining a cluster to which the target data belongs among the clusters classified in the cluster classification operation; and
an abnormality determination numerical value calculation operation of calculating the end point time and the end point area of the target data.

14. The program of claim 13, wherein the abnormality detection operation includes:
an abnormality determination operation of determining whether the semiconductor manufacturing process is abnormal when the target data is collected by comparing the end point time and the end point area of the target data with the end point time and the end point area of the reference data.
